(19) United States
(12) Patent Application Publication
(10) Pub. No.: US 2018/0279019 A1
(43) Pub. Date: Sep. 27, 2018

(54) APPARATUS FOR LAYING PATCH CORDS IN A TELECOMMUNICATION RACK (CABINET)

(71) Applicant: OBSCHESTVO S OGRANICHENNOV OTVETSTVENNOSTYU "UCABLE", Moscow (RU)

(72) Inventor: Boris Alekseevich Khozyainov, Korolev (RU)

(73) Assignee: Boris Alekseevich Khozyainov, Korolev (RU)

(21) Appl. No.: 15/542,460

(22) PCT Filed: Jan. 18, 2016
(86) PCT No.: PCT/RU2016/000010

§ 371 Date: Jul. 10, 2017

(30) Foreign Application Priority Data
Jan. 20, 2015 (RU) 2015101356

(51) Int. Cl. H04Q 1/06; H05K 7/14

(52) U.S. Cl. CPC H04Q 1/06; H05K 7/1491

(57) ABSTRACT

The invention relates preferably to communication technology. It describes an apparatus for laying patch cords in a telecommunication rack (cabinet), or otherwise a cable organizer (manager). The essence of the invention consists in that the apparatus comprises cavities that permit to lay the excess cable of the twice folded patch cords into an interspace in the depth of the rack, passing that excess cable through apertures disposed at the front panel of the apparatus for laying the patch cords.

### FIELD OF THE INVENTION

The present invention relates to communication technology and may be used for laying patch cords in a telecommunication rack (cabinet).

### BACKGROUND OF THE INVENTION

Currently, in server rooms and data centers are commonly used apparatuses for laying patch cords in a telecommunication rack (cabinet), or cable organizers (managers). Patch cords have a fixed length, and the nomenclature of the patch cord lengths is limited. A distance between network ports in a rack does not usually coincide with a patch cord length, therefore, when connecting server ports in a rack by a patch cord, an excess of the patch cord emerges, and that excess is laid in loops into apparatuses for laying patch cords.

A disadvantage of such apparatuses consists in that the patch cord loops are in contact, and the patch cords are jumbled.

### SUMMARY OF THE INVENTION

Thus, the object of the present invention consists in developing such an apparatus for laying patch cords that prevents the jumbling of patch cord cable loops.

In order to achieve said technical result, the present invention provides an apparatus for laying patch cords in a telecommunication rack (cabinet), wherein said apparatus: having at least one cavity (hollow interspace) for laying a patch cord cable, at least 80% of volume of the cavity are disposed behind the front panel of the apparatus in the depth of the rack (cabinet) after placing the apparatus into the rack (cabinet); having an aperture at the front panel, which aperture permitting to lay the patch cord cable in the cavity in such a manner that the patch cord cable folded with a bend and passing through the aperture even number of times crosses at least one imaginary geometric plane passing through three points disposed at the front panel.

The cavity of the apparatus for laying patch cords may have stops preventing the movement of the patch cord cable laid in the cavity into another cavity of the apparatus for laying patch cords. Moreover, the cavity may also have stops preventing the movement of the patch cord cable laid in the cavity into the depth of the rack (cabinet). The stops may be made in the form of walls or stems.

The cavity in the apparatus for laying patch cords may have a composite structure, wherein the depth of the cavity varies by selecting the number of joined structural members.

The cavity may be made of plastic or metal.

The apparatus for laying patch cords may additionally comprise a device for laying a cable in the cavity, which device consisting of a stem and a means ensuring the minimal cable bend radius, which stem and means may be fasten using constant magnets.

The apparatus for laying patch cords may be used for optical or twisted pair cables.

In some instances, the apparatus for laying patch cords may have common body with a cord panel. In this case, the panel may be an optical one provided with LC connectors.

The apparatus for laying patch cords may comprise a device for carrying a patch cord cable horizontally, and have a height of one or two units (U).

The apparatus for laying patch cords may have 24 or more cavities.

A cable having the outer diameter of not more than 4 mm may be placed in the cavity of the apparatus for laying patch cords. Herewith, such cable may occupy more than one cavity in that apparatus.

And finally, the cavity of that apparatus may have dimensions enabling to place the patch cord cable by bending the cable with a radius not more than the minimal bend radius thereof.

### BRIEF DESCRIPTION OF DRAWINGS

In all figures, the same reference numbers mark the same or similar elements.

FIG. 1 shows the front view of the apparatus for laying patch cords in a telecommunication rack (cabinet).

FIG. 2 shows the plan view of the apparatus for laying patch cords in a telecommunication rack (cabinet).

FIG. 3 shows the side elevation view of the cavity stops made in the form of cylinders.

FIG. 4 shows the plan view of device for laying a cable in the cavity.

FIG. 5 shows the side elevation view of device for carrying a patch cord cable horizontally.

FIG. 6 shows the front view of the apparatus for laying patch cords in a telecommunication rack (cabinet) being in coincidence with the cord panel.

### DETAILED DESCRIPTION OF THE INVENTION

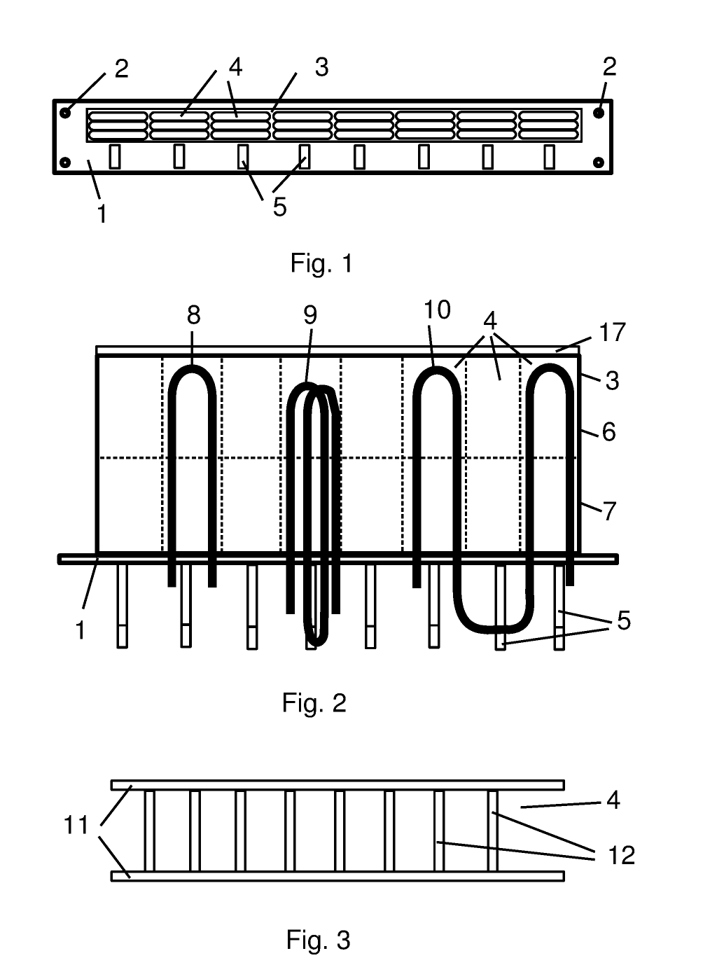

FIG. 1 shows the front view of the apparatus for laying patch cords in a telecommunication rack (cabinet). A front plate 1 made from a sheet of plastic or metal has holes 2 for fastening to the rails of the telecommunication rack. Usually, the apparatus for laying patch cords may have a device for carrying a patch cord cable horizontally, which device may be made, for example, from a metal strip bent as shown in FIG. 5. A distinctive feature of the apparatus for laying patch cords in accordance with the present invention consists in existence of cavities (hollow interspace) 4, three rows with eight cavities in each row, organized in an assembly 3. The assembly 3 with the cavities 4 may be made by molding or cutting. As shown in FIG. 2, the assembly 3 may consist of several parts (reference numbers 6 and 7 divided in FIG. 2 by a horizontal dashed line). The members 6 and 7 may be joined together end-to-end using pins. By varying the number of the members similar to 6 and 7, the cavities of different depth may be made. FIG. 2 shows the sectional plan view of one of said rows of cavities 4 divided by vertical dashed lines. Here are also shown variants of laying a patch cord cable in the cavity 4 (cable connectors are not shown). The most typical is the variant, when a fragment of the cable 8 is folded and pushed with its bend into one of the cavities 4. Thus, having a depth of the cavity 4 equal to 450 mm, an excess of the patch cord cable up to 900 mm may be inserted into the cavity. In this case, a width of the cavity must be such for ensuring the minimum permissible bent radius of the cable; for the UTP wires having the outer diameter of about 6 mm, such radius is equal to 25 mm. If the dimensions of the cavity 4 permit that, then the excess of the patch cord cable may be laid as shown in position 9. When using the patch cords of a small diameter (for example, the Pandiut SD series having the diameter of 3.8 mm), then the permissible bent radius decreases to 15 mm, and the height of the cavity decreases also. Thus, the apparatus for laying patch cords may have twice as many cavities 4, for example, 48. If using a typical cord panel for 24 ports, some patch cords having a small diameter (or usual diameter, but in small quantity) may occupy more than one cavity 4, as shown in position 10 in FIG. 2, and twice as much cable excesses may be laid in the cavity. It is clear from FIG. 2 that each of cables crosses even number of times at least one imaginary geometric plane passing through three points disposed at the front panel 1: the cable 8 crosses it 2 times, and the cables 9 and 10—4 times.

In order for preventing the jumbling of patch cord cables, the cavity interspaces are separated from one another by stops preventing the movement of the patch cord cable laid in the cavity into another cavity. The stops may be made in the process of molding in the form of walls (in this case, the walls may project forward from the front panel for imparting stiffness). In order for the bent portion of the patch cord cable not step out of the cavity in the cabinet recess and not jumble with another cable, one more stop may be used. It is represented by the reference number 17 in FIG. 2, made in the form of wall, i.e. plate fixed at the member 6, for example, by pins or glue.

The stops of the cavity 4 may be made in another way (FIG. 3). If two parallel plates 11 are joined together by cylindrical stems 12 mounted so frequently that the folded cable does not pass between them, then a fully functional cavity results.

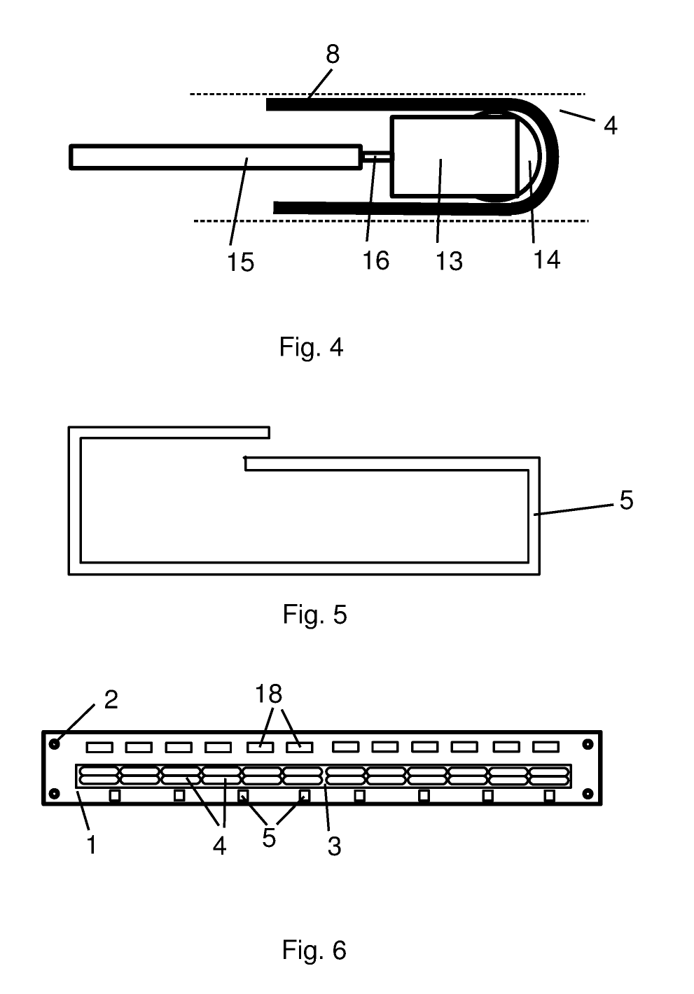

For convenience, the apparatus for laying patch cords in a telecommunication rack (cabinet) may be equipped with a device for laying a cable in the cavity 4 shown in FIG. 4. The device for laying a cable in the cavity comprises a means 13 ensuring the minimal cable bend radius and having a roller 14, and a push bar 15. The push bar 15 may be connected with the means 13 ensuring the minimal cable bend radius using a finger 16 that may be separable or glued to the means 13. If the finger 16 is glued, then the device for laying a cable in the cavity is fully extracted from the cavity. If the connection between the push bar 15 and the means 13 ensuring the minimal cable bend radius is detachable, then, after the push bar 15 being extracted from the cavity 4, the means 13 ensuring the minimal cable bend radius is remained in the cavity and ensures the maintenance of the minimal cable bend radius, which is particularly topical for optical patch cords. The means 13 may be equipped with a constant magnet for the convenient extraction. If one end of the push bar 15 has also the constant magnet, then the end without the magnet may put the means 13 leaving it in the cavity 4, and the end with the magnet may extract the means 13.

It is evident, that the structure of the apparatus for laying patch cords in a telecommunications rack in accordance with the present invention may have different height, for example, of 1 or 2 units (1 unit=44.45 mm).

Sometimes, it is expedient to combine the apparatus for laying patch cords in a telecommunications rack in one body with a patch panel (FIG. 6). For example, an optical patch panel provided with LC connectors for 12 ports (reference number 18 in FIG. 6) requires a low height. The LC cord cable may have a diameter of 2 mm and a bend radius of 15 mm (ITU G.657). Thus, up to 24 cavities 4 may be placed at the space of the front panel 1 having a height of 5 mm. The rest place remaining from the height of 1 unit is more than enough for placing optical ports 18 of the cord panel and devices 5 for carrying a patch cord cable horizontally.

Although the present invention has been described by references to specific embodiments, it is clear for specialists that these illustrative examples, in which various modifications may be made, do not limited the scope of the invention that is determined only by the enclosed claims.

1. An apparatus for laying patch cords in a telecommunication rack (cabinet), wherein said apparatus:
having at least one cavity (hollow interspace) for laying a patch cord cable, at least 80% of volume of said cavity are disposed behind the front panel of said apparatus in the depth of said rack (cabinet), after placing said apparatus into the rack (cabinet);
having an aperture at said front panel, which aperture permitting to lay the patch cord cable in said cavity in such a manner that the patch cord cable folded with a bend and passing through said aperture even number of times crosses at least one imaginary geometric plane passing through three points disposed at said front panel.

2. The apparatus for laying patch cords in accordance with claim 1, wherein said cavity having stops preventing the movement of the patch cord cable laid in said cavity into another cavity of said apparatus.

3. The apparatus for laying patch cords in accordance with claim 1, wherein said cavity having stop(-s) preventing the movement of the patch cord cable laid in said cavity into the depth of the rack (cabinet).

4. The apparatus for laying patch cords in accordance with claim 2 or 3, wherein said stops being walls or stems.

5. The apparatus for laying patch cords in accordance with claim 1, wherein the depth of said cavity varying by selecting the number of joined members of the structure of said cavity.

6. The apparatus for laying patch cords in accordance with claim 1, wherein said cavity being plastic or metal.

7. The apparatus for laying patch cords in accordance with claim 1, wherein said apparatus comprising a device for laying a cable in the cavity, which device consisting of a stem and a means ensuring the minimal cable bend radius.

8. The apparatus for laying patch cords in accordance with claim 7, wherein said stem and means ensuring the minimal cable bend radius having a detachable connection.

9. The apparatus for laying patch cords in accordance with claim 8, wherein said stem and/or means ensuring the minimal cable bend radius comprising constant magnets.

10. The apparatus for laying patch cords in accordance with claim 1, wherein said cable being optical or comprising a twisted pair.

11. The apparatus for laying patch cords in accordance with claim 1, wherein said apparatus having a common body with a pacth panel.

12. The apparatus for laying patch cords in accordance with claim 11, wherein said cord panel being optical.

13. The apparatus for laying patch cords in accordance with claim 12, wherein said cord panel comprising LC couplers.

14. The apparatus for laying patch cords in accordance with claim 11, wherein said apparatus comprising a device for carrying a patch cord cable horizontally.

15. The apparatus for laying patch cords in accordance with claim 1, wherein said apparatus having a height of one or two units (U).

16. The apparatus for laying patch cords in accordance with claim 1, wherein said apparatus having 24 or more cavities.

17. The apparatus for laying patch cords in accordance with claim 1, wherein said cable having the outer diameter of not more than 4 mm.

18. The apparatus for laying patch cords in accordance with claim 17, wherein said cable occupying more than one said cavity.

19. The apparatus for laying patch cords in accordance with claim 1, wherein said cavity having dimensions enabling to place said patch cord cable by bending said cable with a radius not more than the minimal bend radius thereof.
